(19) United States
(12) Patent Application Publication
(10) Pub. No.: US 2024/0074433 A1
(43) Pub. Date: Mar. 7, 2024

(54) METHOD AND APPARATUS FOR PRESERVATION OF BIOLOGICAL MATERIAL

(71) Applicant: VITRAFY LIFE SCIENCES LIMITED, Hobart (AU)

(72) Inventors: Sean Cameron, Hobart (AU); Brent Owens, Hobart (AU); Brian Taylor, Hobart (AU)

(73) Assignee: VITRAFY LIFE SCIENCES LIMITED, Hobart (AU)

(21) Appl. No.: 18/272,310

(22) PCT Filed: Jan. 14, 2021
(86) PCT No.: PCT/AU2021/050024

§ 371 Date: Jul. 13, 2023

(51) Int. Cl. A01N 1/02; F25D 17/02

(52) U.S. Cl. CPC A01N 1/0284; A01N 1/0257; F25D 17/02; F25D 2400/30

(57) ABSTRACT

An apparatus (10) for preserving biological material. The apparatus (10) has an insert (4) configured to be arranged within an outer insulated tank (2), the insert (4) defining a compartment (6) for receiving biological material. Inflow of a heat exchange fluid into the compartment (6) from the outer insulated tank (2) is at or adjacent one face of the insert (4), while outflow of the heat exchange fluid out of the compartment 6 to the outer insulated tank (2) is at or adjacent said face of the insert (4). The compartment (6) has a wall having a series of apertures to accommodate a continuous heat exchange fluid flow through the apparatus such that, in operation, biological material in the compartment (6) is immersed in the heat exchange fluid to exchange heat with the heat exchange fluid for freezing of said biological material.

### FIELD OF THE INVENTION

The present invention relates to methods of preserving biological material and apparatuses for preserving biological material.

### BACKGROUND

The ability to store red blood cells (RBCs) outside of the body has been regarded as a life-saving practice for many years. More recently, the usage of refrigerated stored RBCs in transfusion medicine has been under extensive evaluation. During refrigerated storage RBCs progressively deteriorate and infusion of prolonged stored RBCs has been linked to adverse clinical outcome in terms of postoperative infections, length of hospital stay and mortality.

Concerns regarding the infusion of stored RBCs still remains and a restrictive transfusion strategy is currently being favoured. This has resulted in a revived interest in cryopreservation. Storage of RBCs at ultra-low temperatures halts the cellular metabolism and subsequently prevents the progressive cellular deterioration that has been linked to adverse clinical outcome.

Initially, cryopreservation appeared a promising approach for maintaining RBCs viable for prolonged periods of time. However, the clinical applicability of cryopreserved RBCs (commonly known as “frozen RBCs”) was hampered by the expensive, time-consuming and inefficient nature of this preservation method.

### Requirements of Refrigerated Stored RBCs

Currently RBCs are routinely stored at 2-6° C. for a maximum of 5 to 6 weeks, depending on the retention of viable RBCs. Cryopreservation, on the other hand, enables storage of RBCs for years. Cryopreservation is currently a valuable approach for long-term storage of RBCs from donors with rare blood groups and for military deployment. However, stockpiling cryopreserved RBCs can also be beneficial in emergency or clinical situations, where the demand exceeds the supply of RBCs. The shelf life of cryopreserved RBCs using current methods is up to ten years.

International guidelines require that haemolysis in a refrigerated RBC storage unit must remain below allowable levels (i.e., 0.8% in Europe and 1% in The United States) and that at least 75% of the infused RBCs must still circulate 24 hours after infusion.

However, the guidelines do not specifically reflect the RBCs' ability to function after infusion.

### Quality of Stored RBCs

Although storage at 4° C. slows down the biochemical processes in the RBCs, cellular metabolism is not completely suppressed at these temperatures. During refrigerated storage a variety of changes have been observed that could compromise the RBCs' ability to function after infusion. These changes include decreased concentrations of 2,3-diphosphoglycerate (DPG), adenosine triphosphate (ATP) and membrane sialic acid content. Other changes include translocation of phosphatidylserine (PS) to the cell surface, oxidative injury to membrane lipids and proteins, shape change to spheroechinocytes, membrane blebbing and accumulation of potassium, free haemoglobin (Hb), cytokines, bioactive lipids and (pro-coagulant) microvesicles in the RBC storage unit.

The RBCs' rheologic properties also become impaired during refrigerated storage. Refrigerated RBCs demonstrate an increased tendency to aggregate and adhesion to endothelial cells (ECs), as well as reduced deformability from the second week of storage. These changes may hamper the RBCs' ability to function properly in the microcirculation.

Storage of RBCs at ultra-low temperatures ceases the biological activity of RBCs, enabling them to be preserved for prolonged periods of time. In general, either high concentrations of cryoprotective additives or rapid freezing rates are necessary to prevent cell damage. At slow cooling rates, extra-cellular ice formation will occur. As ice forms, the solute content of the unfrozen fraction becomes more concentrated. The resulting osmotic imbalance causes fluid to move out of the RBC and intracellular dehydration occurs. On the other hand, at rapid cooling rates the RBC cytoplasm becomes super-cooled and intracellular ice formation occurs, which subsequently can lead to mechanical damage.

In order to minimise freezing damage, it has been thought that cryoprotective additives are crucial. Over the years, different non-permeating and permeating additives for the cryopreservation of RBCs have been investigated. Non-permeating additives such as hydroxyethyl starch and polyvinylpyrrolidone, as well as a variety of glycols and sugars appeared promising because it was proposed that removal from thawed RBCs prior to transfusion was not required.

Conversely, the permeating additive glycerol is known for its ability to protect RBCs at ultra-low temperatures. The concentration of glycerol that is necessary to protect the RBCs is dependent on the cooling rate and the storage temperature. Glycerol protects the RBCs by slowing the rate and extent of ice formation while minimising cellular dehydration and solute effects during freezing.

### Requirements of Cryopreserved RBCs

Although preservation of RBCs at ultra-low subzero temperatures enables them to be preserved for years, once thawed, the shelf life of RBCs is limited. Deglycerolised RBCs are primarily stored in saline-adenine-glucose-mannitol (SAGM) preservation solution for up to 48 hours or in AS-3 preservation solution for up to 14 days. Cryopreserved RBCs need to be deglycerolised to reduce the residual glycerol content to below 1%. Furthermore, the RBCs are subject to the abovementioned international guidelines requiring that haemolysis in the RBC units must remain below allowable levels (i.e. 0.8% in Europe and 1% in The United States) and that the RBC post-thaw recovery after deglycerolisation (i.e. freeze-thaw-wash recovery) must exceed 80%. Also, at least 75% of cryopreserved RBCs must still circulate 24 hours after infusion.

Freezing Methods with Glycerol

Currently there are two freezing methods accepted for the preservation of RBCs with glycerol.
1. RBCs can be frozen rapidly in liquid nitrogen using a low-glycerol method (LGM) with a final concentration of approximately 20% glycerol (wt/vol) at temperatures below −140° C.
2. RBCs can be frozen slowly using a high-glycerol method (HGM), allowing storage of RBC units with a final concentration of approximately 40% (wt/vol) glycerol at temperatures between −65° C. and −80° C.
3. RBCs can be rapidly frozen using standard formations of 10% dimethyl sulfoxide (DMSO).

Cryopreserved RBCs are less efficient due to the cellular losses that occur during the processing procedure. This cell loss is more pronounced in HGM cryopreserved RBCs (approximately 10-20%) since these RBCs require more extensive washing. However, despite the higher yield of RBCs with the LGM, it is generally considered that HGM cryopreserved RBCs can tolerate wide fluctuations in temperature during freezing and are more stable during post-thaw storage. In addition, HGM cryopreserved RBCs do not require liquid nitrogen which eased storage and transportation conditions. Consequently, the HGM is currently the most applicable RBC freezing method in Europe and the United States.

The storage method associated with the HGM of cryopreservation results in intracellular dehydration due to the high glycerol content and storage temperature ranges. Further, the HGM method is, in many applications, associated with increased cell death because of the slow transition of the preserved cells and surrounding materials from the fluid to the solid state, or vice versa, leading to osmotic shock damage.

In contrast, LGM minimizes solute concentration effects and thereby osmotic shock effects, but intracellular ice formation may become an issue if the rapid cooling rate does not allow sufficient time for water to migrate out of the cells.

Preferred embodiments of the present invention seek to utilise lower glycerol content, thereby minimising cellular dehydration and solute effects, while extending the shelf life of cryopreserved RBCs.

Other preferred embodiments seek to reduce or eliminate the use of cryoprotectants while maintaining cell viability.

### SUMMARY

While the above background relates to RBCs, it will be appreciated that embodiments of the present invention may be applied to other biological material such as stem cells (eg from bone marrow, umbilical cord blood, amniotic fluid, etc), other blood products (eg leucocytes, plasma, platelets, and serum), microorganisms such as bacteria and fungi, germ cells and associated materials such as seminal fluid, tumour cells, colostrum, vaccines, and plant cells.

As used herein, “biological material” includes the following non-exhaustive list of materials: blood, plasma, platelets, genus, bacteria, organs, seminal fluid, eggs, colostrum, skin, serum, vaccines, stem cells, umbilical cords, bone marrow, and the other materials listed above.

According to a first aspect of the present invention, there is provided an apparatus for preserving biological material, comprising an insert configured to be arranged within an outer insulated tank, the insert defining a compartment for receiving biological material, wherein inflow of a heat exchange fluid into the compartment from the outer insulated tank is at or adjacent one face of the insert, and outflow of the heat exchange fluid out of the compartment to the outer insulated tank is at or adjacent said face of the insert, the compartment comprising a wall having a series of apertures to accommodate a continuous heat exchange fluid flow through the apparatus such that, in operation, biological material in the compartment is immersed in the heat exchange fluid to exchange heat with the heat exchange fluid for freezing of said biological material.

According to a second aspect of the present invention, there is provided a method of preserving biological material, comprising:
a. determining the total surface area of an approximated geometry of a sample of the biological material, wherein the biological material and any packaging define a sample;
b. estimating thermal properties of the sample;
c. performing computational fluid dynamics analysis on the sample within said compartment of the apparatus of the aspect described above based on flow constraints including any one or more of: an approximated geometry of the sample; thermal properties of the sample; the apparatus geometry; predetermined arrangement of sample in the apparatus; a predetermined inlet temperature of heat exchange fluid; and a predetermined increase in temperature of the heat exchange fluid from inlet to outlet;
d. approximating the onset of liquid-solid phase transition for the sample;
e. determining an average temperature reduction rate of the core of the sample at a predetermined sample surface temperature up to about the onset of phase transition and corresponding heat exchange fluid flow rate required to obtain a predetermined slow cooling rate;
f. determining an average temperature reduction rate of the core of the sample at a predetermined sample surface temperature from about the onset of phase transition and corresponding heat exchange fluid flow rate required to obtain a predetermined rapid cooling rate;
g. cooling the sample in said compartment of the apparatus of the aspect described above at said slow cooling rate up to about the onset of phase transition;
   cooling the sample in said compartment at the rapid cooling rate from about the onset of phase transition.

According to a third aspect of the present invention, there is provided a method of preserving a biological material within an apparatus having a compartment in which the biological material is stored, and a pump arrangement for pumping a heat exchange fluid into and/or from the compartment, the method comprising: adjusting an inflow of heat exchange fluid into the compartment and/or an outflow of heat exchange fluid from the compartment based on thermal properties of the biological material and at least one of a pumping capability of the pumping arrangement, the heat exchange fluid, and a temperature of the biological material.

According to a fourth aspect of the present invention, there is provided a method of determining an amount of cryoprotectant to be added to a biological material prior to preservation, comprising:
a. determining the total surface area of an approximated geometry of the biological material, including an initial amount of cryoprotectant, to be preserved, wherein the biological product, cryoprotectant and any packaging define a sample;
b. estimating thermal properties of the sample;
c. performing computational fluid dynamics analysis on the sample within said compartment of the apparatus of the aspect described above based on flow constraints including any one or more of: an approximated geometry of the sample; thermal properties of the sample; the apparatus geometry; predetermined arrangement of sample in the apparatus; a predetermined inlet temperature of heat exchange fluid; and a predetermined increase in temperature of the heat exchange fluid from inlet to outlet;
d. approximating the onset of liquid-solid phase transition for the sample;
e. determining an average temperature reduction rate of the core of the sample at a predetermined sample surface temperature up to about the onset of phase transition and corresponding heat exchange fluid flow rate required to obtain a predetermined slow cooling rate;
f. determining an average temperature reduction rate of the core of the sample at a predetermined sample surface temperature from about the onset of phase transition and corresponding heat exchange fluid flow rate required to obtain a predetermined rapid cooling rate; and
g. if the heat exchange fluid flow rate calculated at step (f) corresponds to a pump duty or an evaporator duty of the apparatus that is above a predetermined pump duty or predetermined evaporator duty respectively, selecting an amount of cryoprotectant that is a predetermined amount more than the initial amount to define a new initial amount or, if the heat exchange fluid flow rate calculated at step (f) corresponds to a pump duty or an evaporator duty that is equal to or less than the predetermined pump duty or predetermined evaporator duty respectively, selecting the initial amount of cryoprotectant as said amount of cryoprotectant to be added to a biological material prior to preservation; and
h. if the heat exchange fluid flow rate calculated at step (f) corresponds to a pump duty or an evaporator duty that is above the predetermined pump duty or predetermined evaporator duty respectively, repeating steps (a) to (g) until the heat exchange fluid flow rate calculated at step (f) corresponds to a pump duty or an evaporator duty that is equal to or less than the predetermined pump duty or predetermined evaporator duty respectively

According to a fifth aspect of the present invention, there is provided an apparatus for thawing frozen preserved biological material comprising a thawing tank for receiving biological material, said biological material being held within the tank in a structure comprising one or more of a tray, a rack and a basket, a tank inlet via which thawing fluid is introduced into the tank, and a tank outlet via which thawing fluid is removed from the tank, wherein the tank is configured to accommodate a continuous thawing fluid flow through the apparatus such that, in operation, biological material in the tank is immersed in the thawing fluid to exchange heat with the thawing fluid for thawing of said biological material.

According to a sixth aspect of the present invention, there is provided a method of thawing a frozen preserved biological material, comprising:
a. determining the total surface area of an approximated geometry of the biological material, wherein the biological material and any packaging define a sample;
b. estimating thermal properties of the sample;
c. performing computational fluid dynamics analysis on the sample within said tank of a thawing apparatus of the aspect described above based on flow constraints including any one or more of: an approximated geometry of the sample; thermal properties of the sample; the apparatus geometry; predetermined arrangement of sample in the apparatus; a predetermined inlet temperature of thawing fluid; and a predetermined decrease in temperature of the thawing fluid from inlet to outlet;
d. approximating the onset of solid-liquid phase transition for the sample; thawing the frozen preserved biological product for a duration up to the onset of solid-liquid transition determined at step (d).

### BRIEF DESCRIPTION

Embodiments of the present invention will now be described, by way of non-limiting example only, with reference to the accompanying drawings, in which:

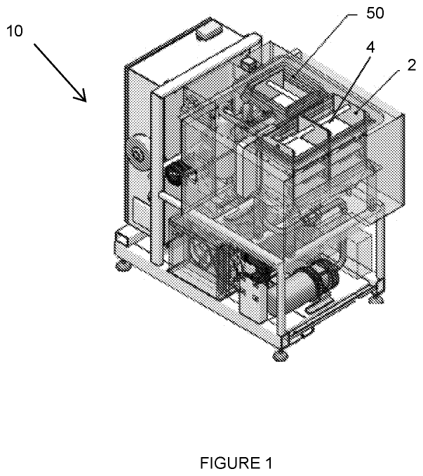

FIG. 1 is an upper perspective view of an apparatus for preserving biological material according to one embodiment;

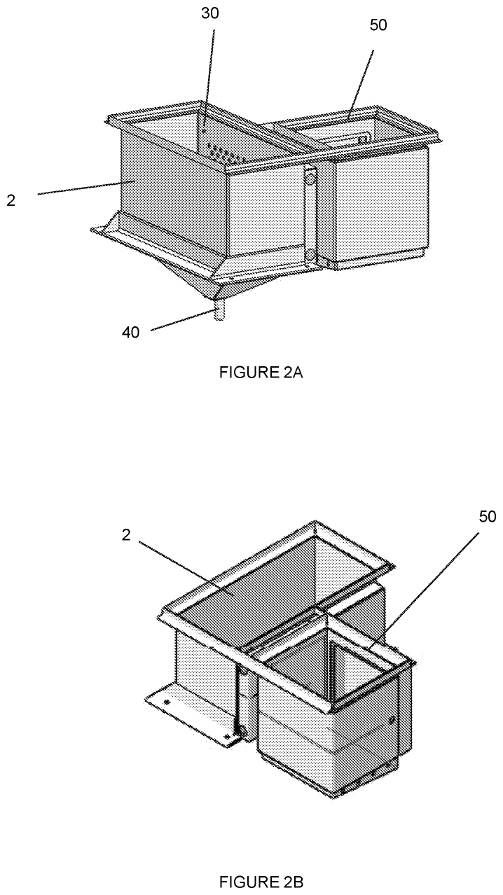

FIGS. 2A and 2B are upper perspective views of tanks of the apparatus of FIG. 1 according to one embodiment;

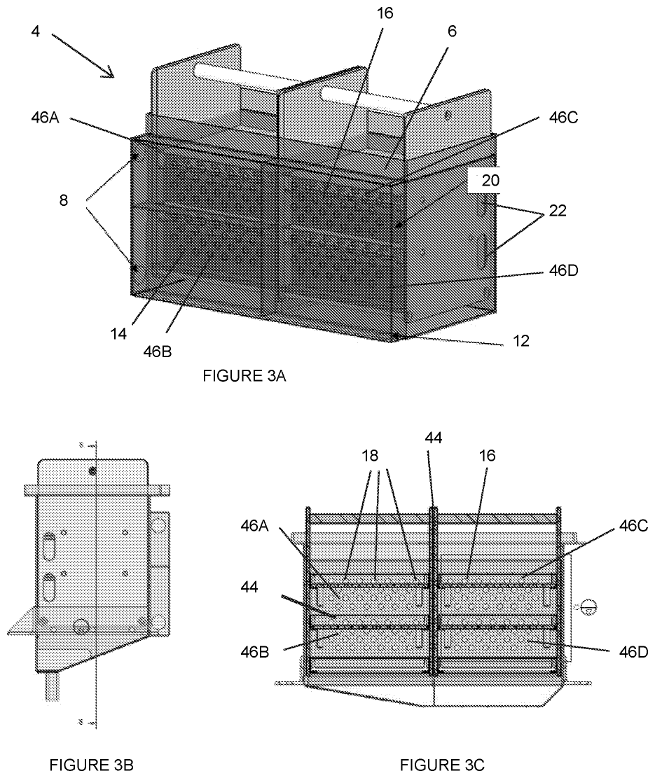

FIGS. 3A, 3B and 3C illustrate an insert for the tank of the apparatus of FIG. 1 according to one embodiment;

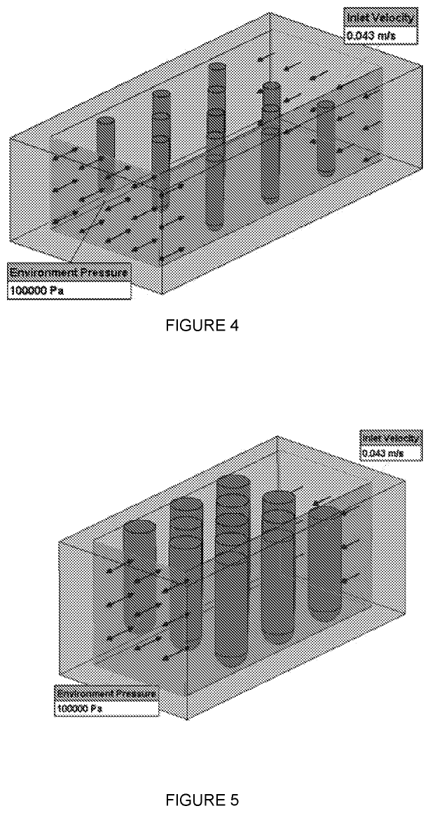

FIG. 4 illustrates a model of an array of 0.5 ml cryovials for simulating freezing within a compartment of the apparatus;

FIG. 5 illustrates a model of an array of 2 ml cryovials for simulating freezing within a compartment of the apparatus;

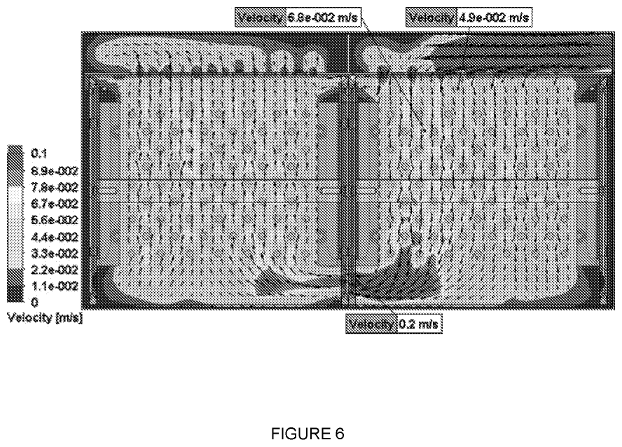

FIG. 6 is a plan view of heat exchange fluid flow from simulation of the model of FIG. 4, taken midplane through the cryovials;

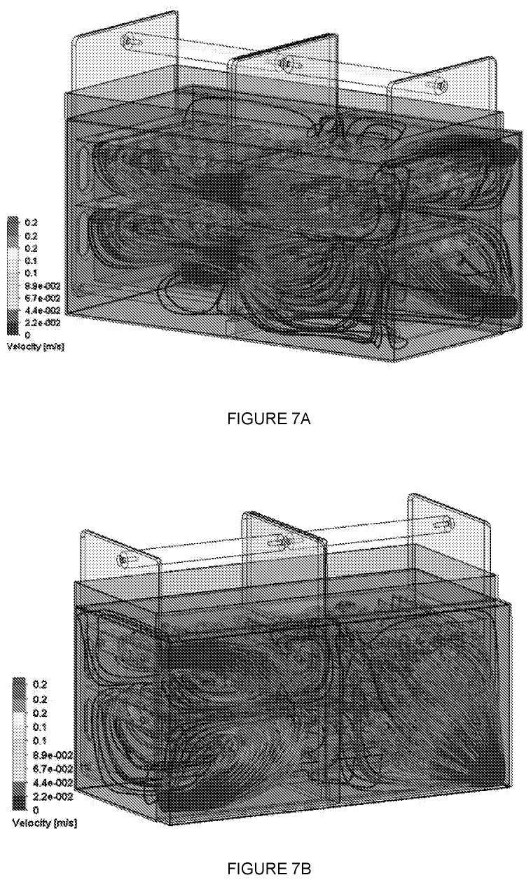

FIGS. 7A and 7B are front and rear perspective views respectively of heat exchange fluid flow from simulation of the model of FIG. 4;

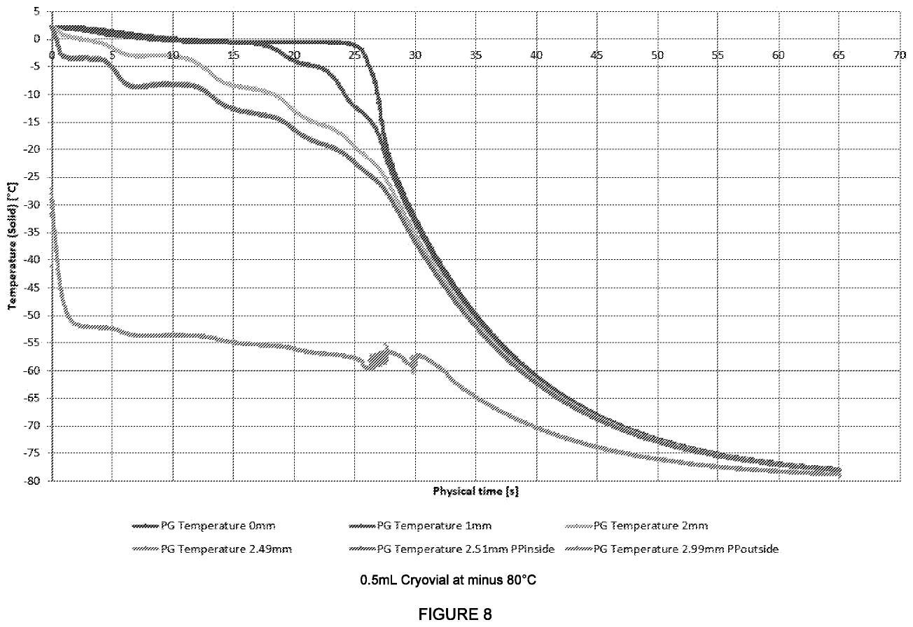

FIG. 8 is a temperature-time plot of the central cryovial of the model of FIG. 4, frozen to about −80° C. within about 65 seconds;

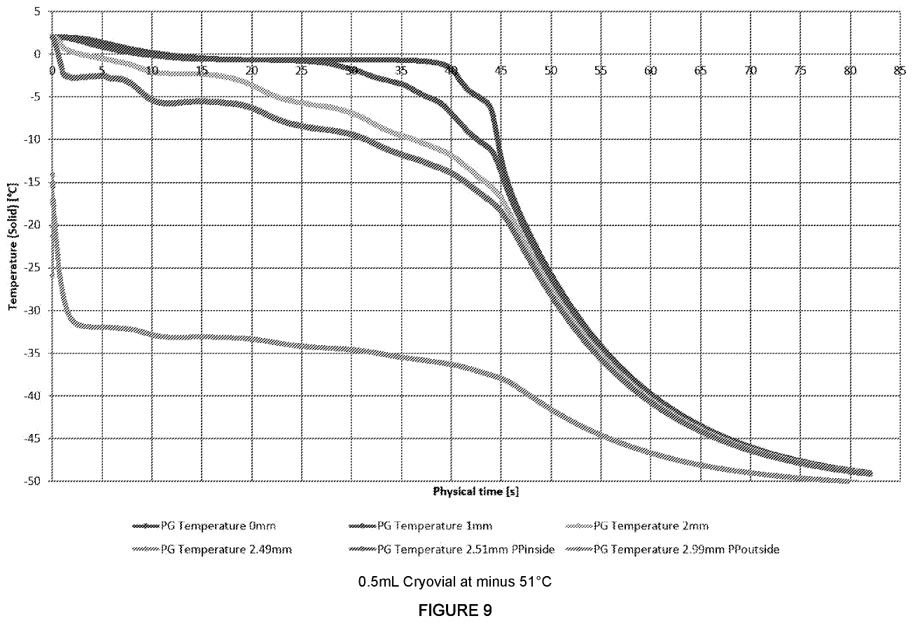

FIG. 9 is a temperature-time plot of the central cryovial of the model of FIG. 4, frozen to about −51° C. within about 80 seconds;

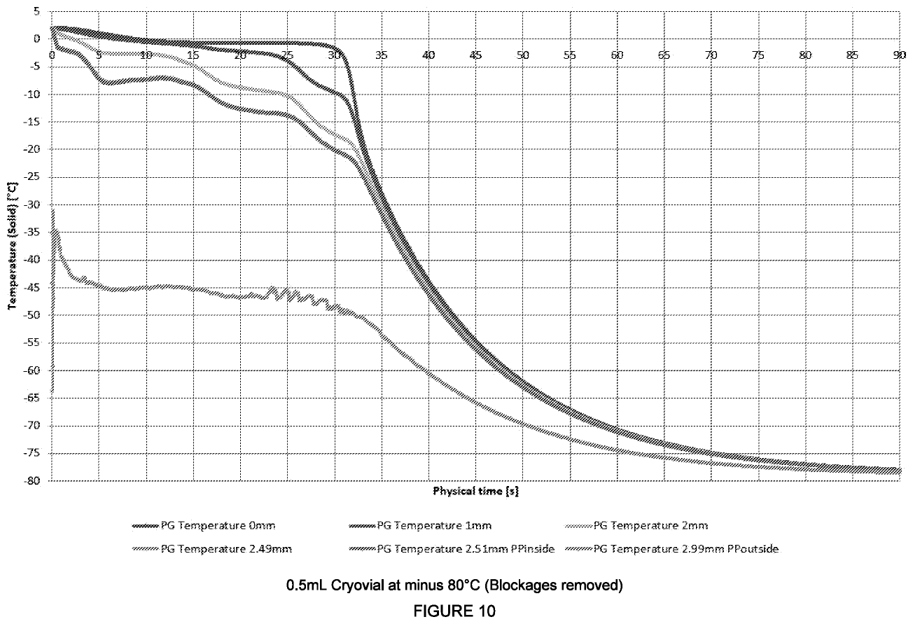

FIG. 10 is a temperature-time plot of the central cryovial of the model of FIG. 4, frozen at the same rate as the simulation of FIG. 8, but with the baffle removed from the insert;

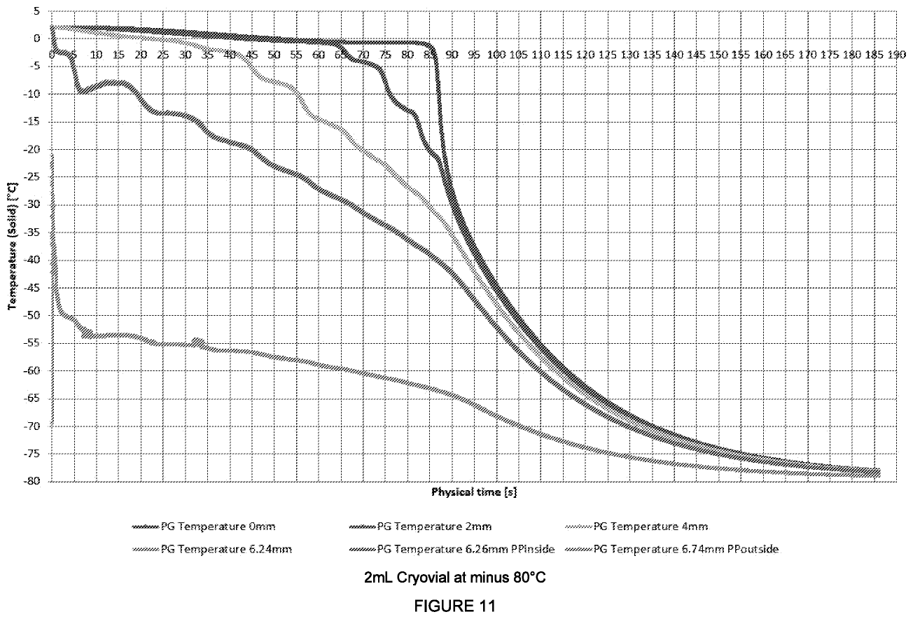

FIG. 11 is a temperature-time plot of the central cryovial of the model of FIG. 5, frozen to about −80° C. within about 185 seconds;

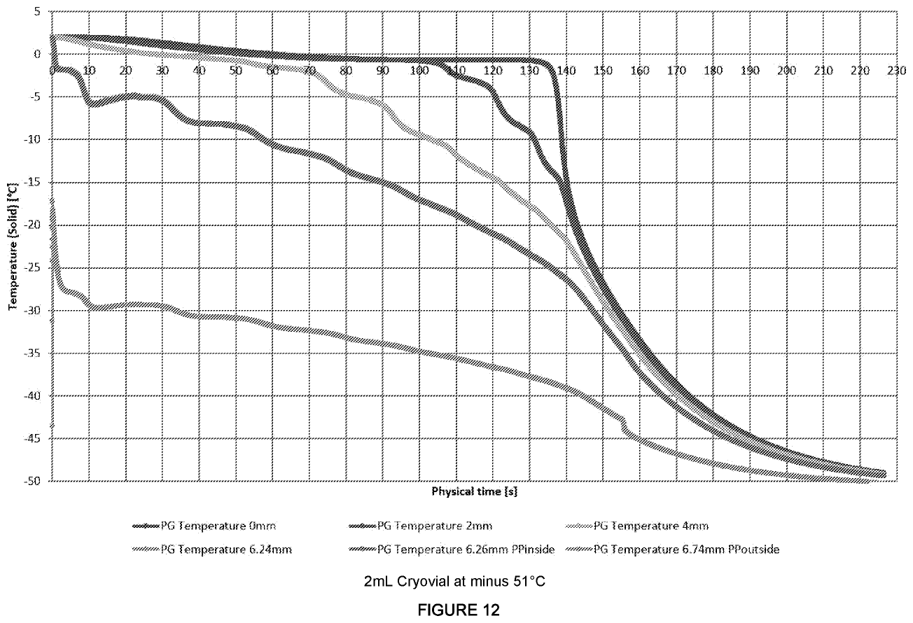

FIG. 12 is a temperature-time plot of the central cryovial of the model of FIG. 5, frozen to about −51° C. within about 220 seconds;

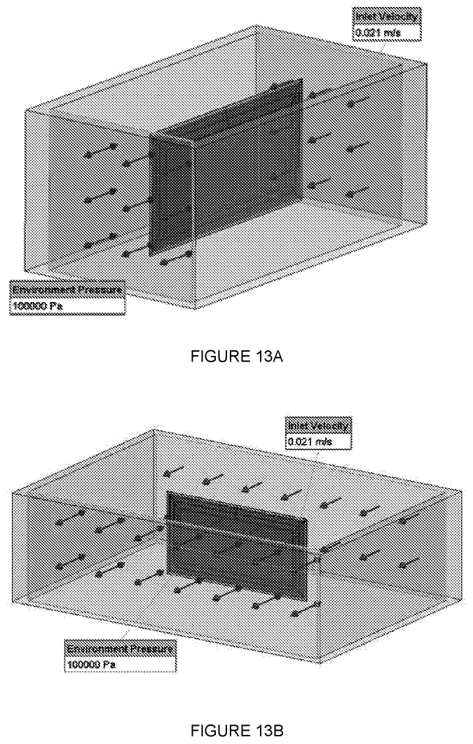

FIG. 13A illustrates a simulation model of a blood bag suspended within a compartment of the apparatus, with heat transfer fluid inflow substantially perpendicular to a narrow side face of the bag;

FIG. 13B illustrates a simulation model of a blood bag suspended within a compartment of the apparatus, with heat transfer fluid inflow substantially perpendicular to a wide front face of the bag;

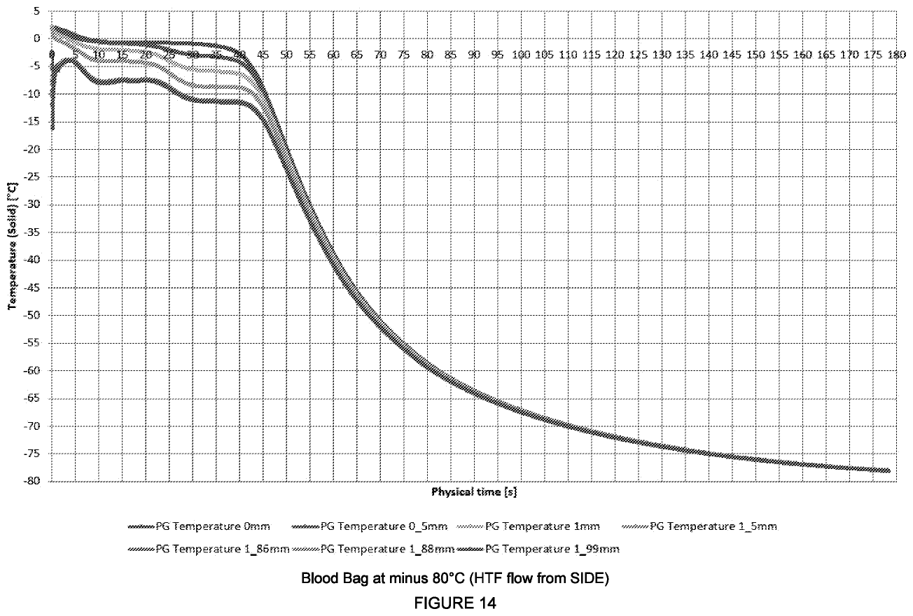

FIG. 14 is a temperature-time plot of the blood bag of the model of FIG. 13A, frozen to about −80° C. within about 180 seconds;

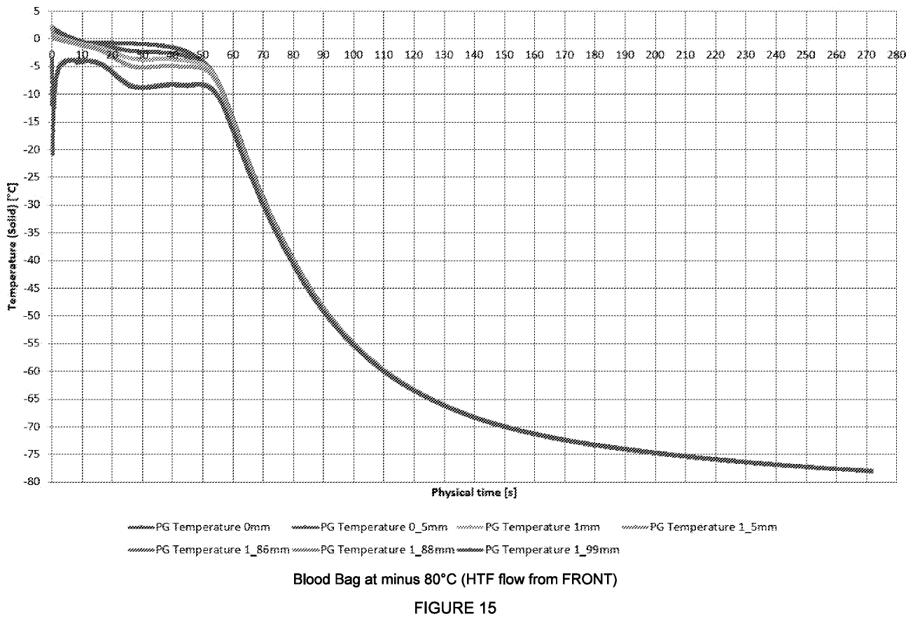

FIG. 15 is a temperature-time plot of the blood bag of the model of FIG. 13B, frozen to about −80° C. within about 270 seconds;

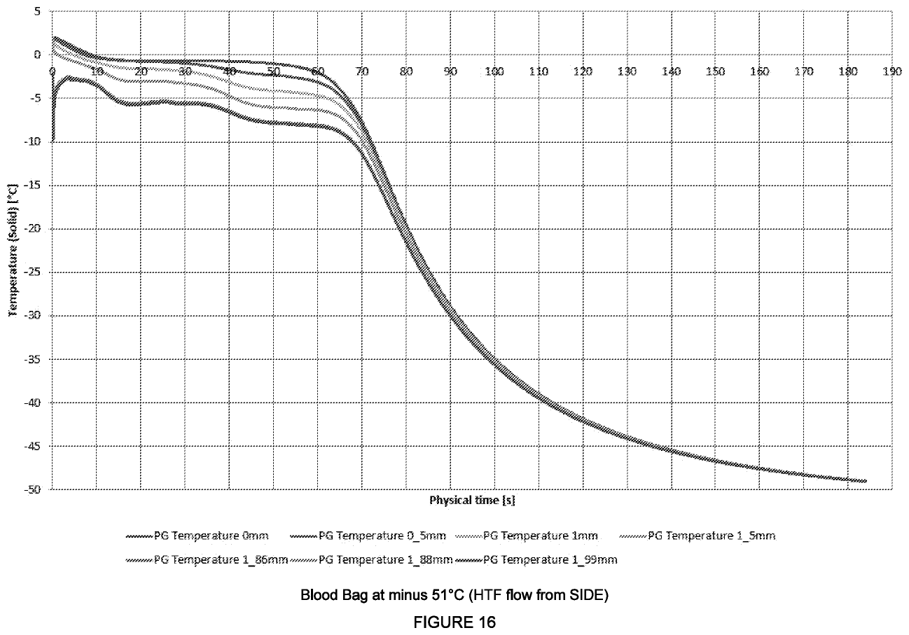

FIG. 16 is a temperature-time plot of the blood bag of the model of FIG. 13A, frozen to about −51° C. within about 180 seconds;

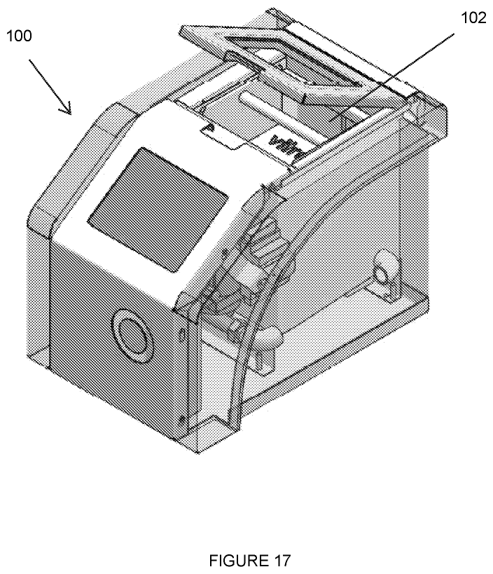

FIG. 17 is an upper perspective view of a thawing apparatus according to one embodiment;

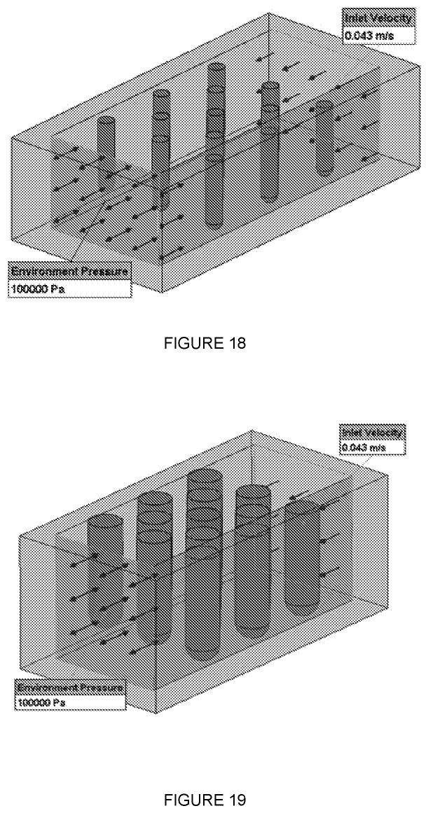

FIG. 18 illustrates a model of an array of 0.5 ml cryovials for simulating thawing within a compartment of the thawing apparatus;

FIG. 19 illustrates a model of an array of 2 ml cryovials for simulating thawing within a compartment of the thawing apparatus;

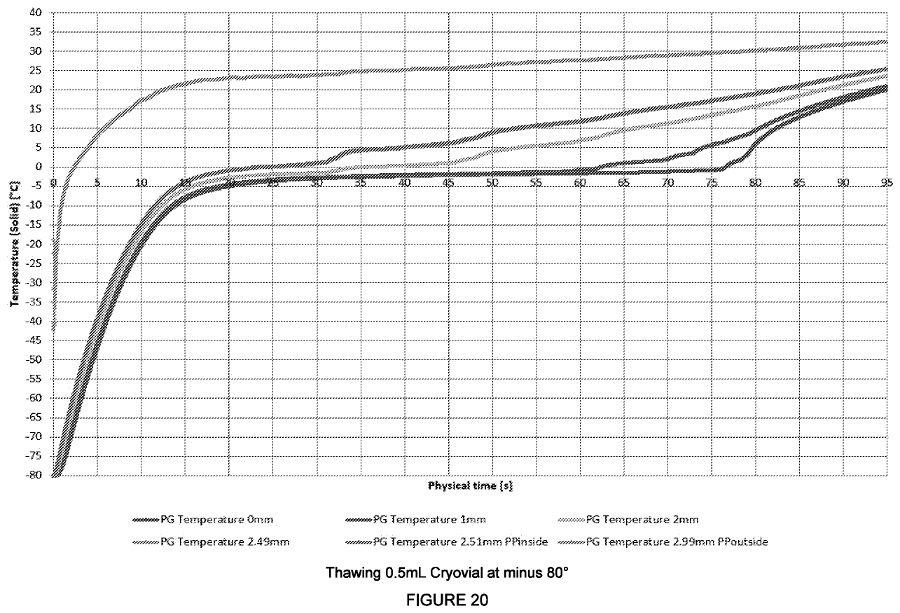

FIG. 20 is a temperature-time plot of the central cryovial of the model of FIG. 18, thawed from about −80° C.;

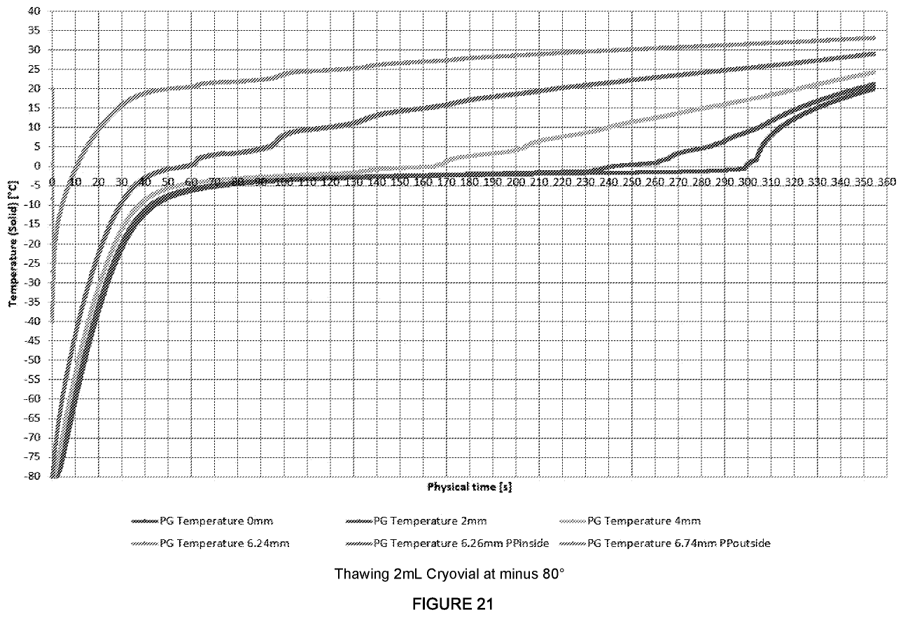

FIG. 21 is a temperature-time plot of the central cryovial of the model of FIG. 19, thawed from about −80° C.;

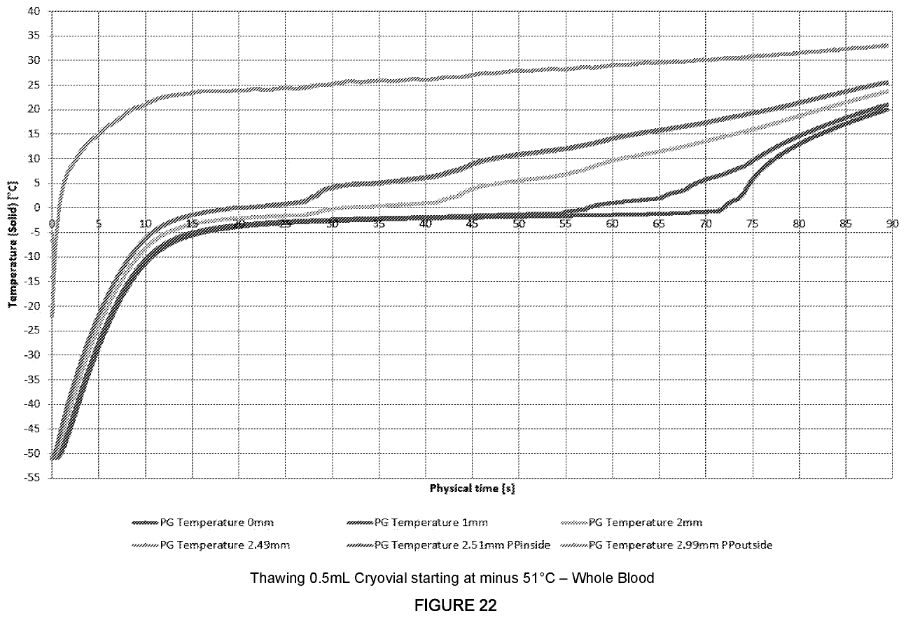

FIG. 22 is a temperature-time plot of the central cryovial of the model of FIG. 19 containing red blood cells without cryoprotectant, thawed from about −51° C.;

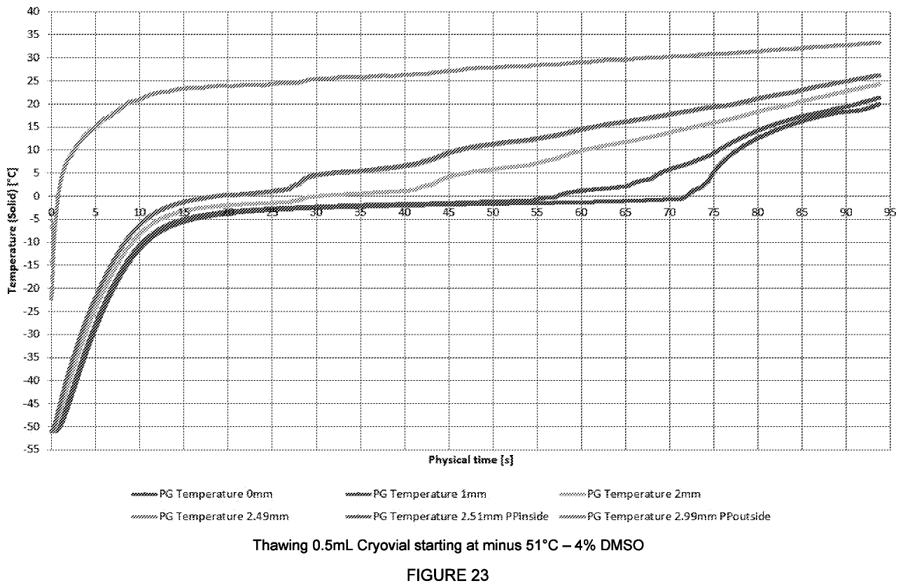

FIG. 23 is a temperature-time plot of the central cryovial of the model of FIG. 19 containing red blood cells with 4% dimethyl sulfoxide (DMSO) as cryoprotectant, thawed from about −51° C.;

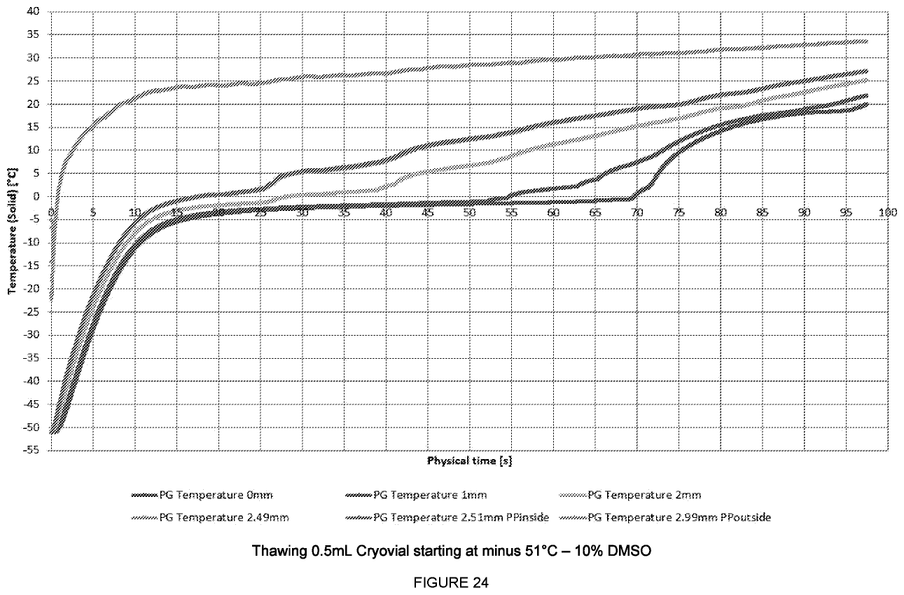

FIG. 24 is a temperature-time plot of the central cryovial of the model of FIG. 19 containing red blood cells with 10% dimethyl sulfoxide (DMSO) as cryoprotectant, thawed from about −51° C.;

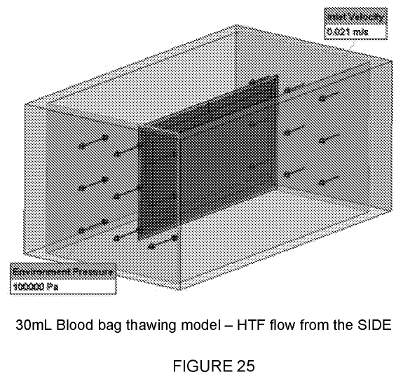

FIG. 25 illustrates a simulation model of a blood bag suspended within a compartment of the thawing apparatus, with thawing fluid inflow substantially perpendicular to a narrow side face of the bag;

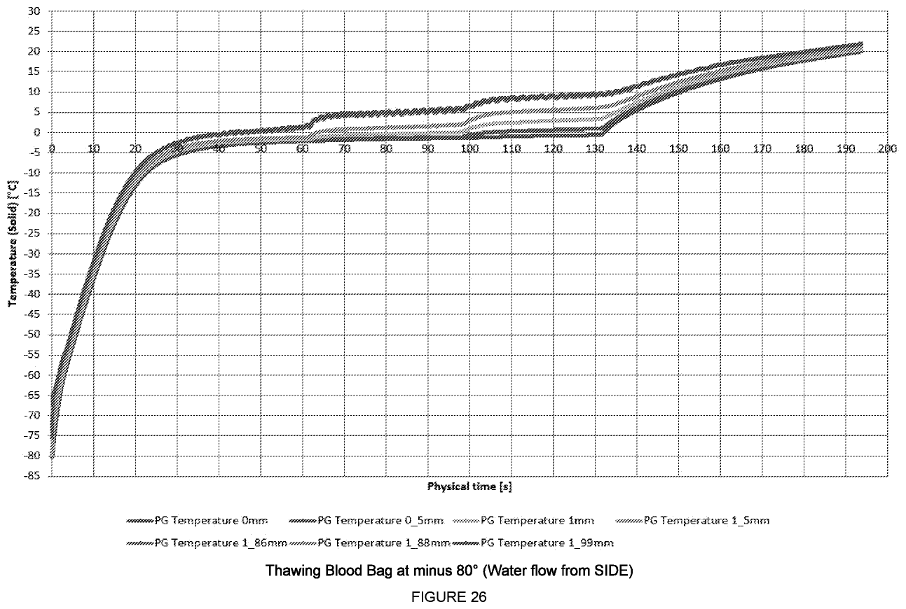

FIG. 26 is a temperature-time plot of the blood bag of the model of FIG. 25, thawed from about −80° C.;

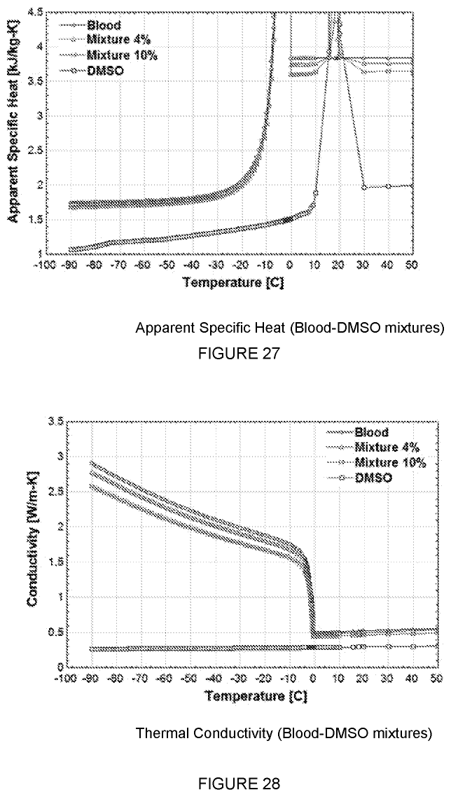

FIGS. 27 and 28 are reference plots of apparent specific heat and thermal conductivity respectively for blood mixtures with varying DMSO concentrations;

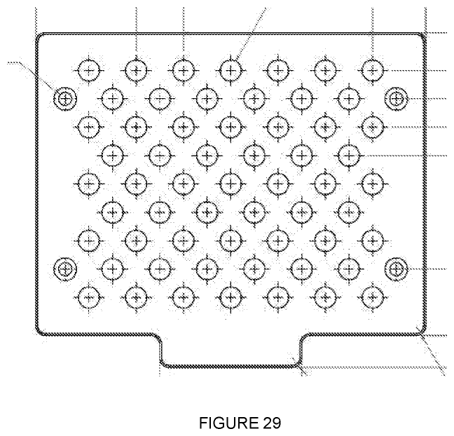

FIG. 29 illustrates a rack for holding a plurality of cryovials within the compartment of the apparatus;

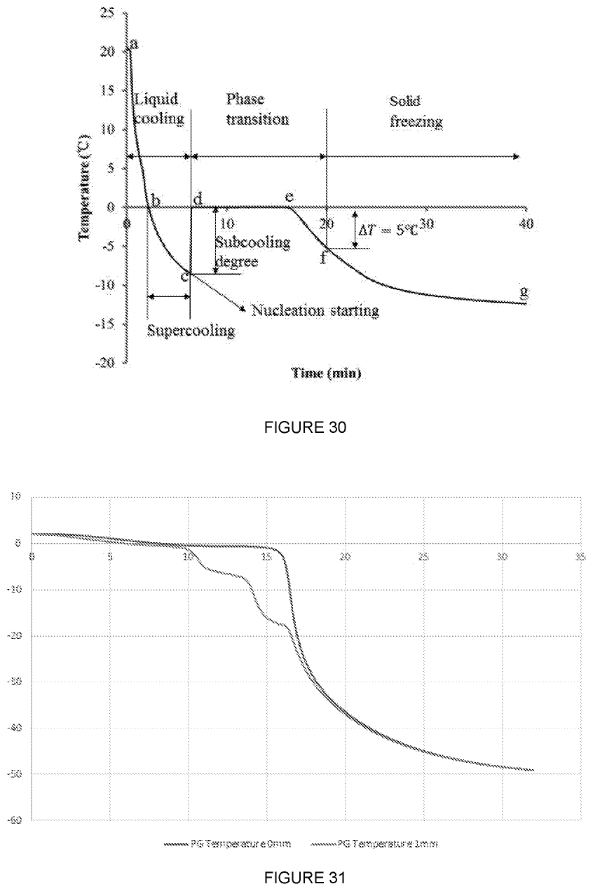

FIG. 30 is a generic freezing curve illustrating liquid-solid phase transition;

FIG. 31 is a freezing curve of a sample of red blood cells frozen using the two-phase cooling method according to one embodiment; and

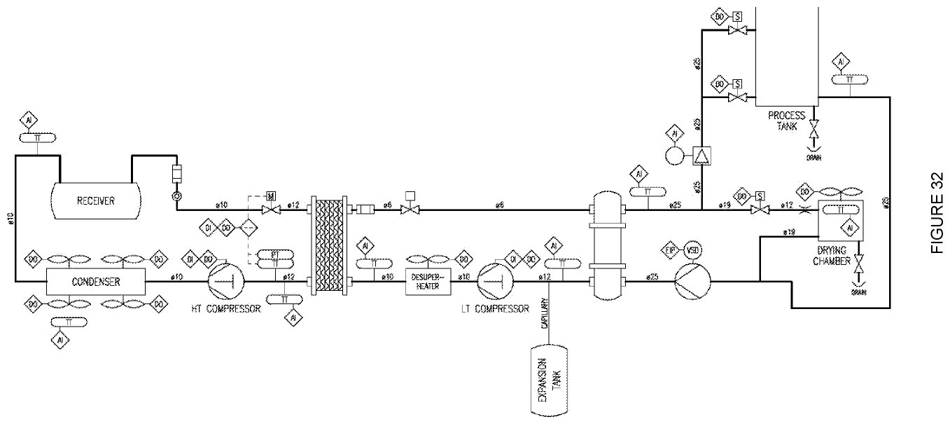

FIG. 32 is a piping and instrumentation diagram of the apparatus according to one embodiment.

### DETAILED DESCRIPTION

FIGS. 1 to 3 illustrate an apparatus 10 for preserving biological material according to one embodiment, comprising an insert 4 configured to be arranged within an outer insulated tank/immersion tank 2, the insert 4 defining a compartment 6 for receiving biological material, wherein inflow (through inlets 8) of a heat exchange fluid into the compartment from the outer insulated tank 2 is at or adjacent one face 14 of the insert, and outflow (through outlets 12) of the heat exchange fluid out of the compartment to the outer insulated tank is at or adjacent said face 14 of the insert.

The compartment 6 comprises a wall 16 having a series of apertures 18 to accommodate a continuous heat exchange fluid flow through the apparatus such that, in operation, biological material in the compartment is immersed in the heat exchange fluid to exchange heat with the heat exchange fluid for freezing of said biological material. Each of the apertures has a diameter or width of between about 5 mm and 20 mm, preferably about 10 mm.

The insert 4 comprises a baffle 20 configured to direct flow of the heat exchange fluid through the compartment along one or more specific pathways. In the illustrated embodiment (with particular reference to FIG. 3A), flow of the heat exchange fluid is directed from the inlets 8 adjacent the front side of the insert, through the compartment 6 and out of intermediate outlets 22, then back to the front side of the insert and out of outlets 12. The specific flow path directed by baffle 20 improves circulation of heat exchange fluid through the compartment and reduces hot spots. Further, the specific configuration of inflow and outflow of heat exchange fluid at or adjacent a common face of the insert 4 forces the fluid to circulate through the entire compartment 6, with the fluid rebounding off the opposite face of the insert 4 to improve circulation (see, eg the flow models in FIGS. 4 and 5, for simulating fluid rebounding off the opposite face of the insert).

The compartment 6 is configured to receive a structure for holding the biological material, the structure being one or more of a tray, a rack and a basket. An example of a rack 42 configured to hold a plurality of vials is illustrate in FIG. 29. The compartment comprises a plurality of internal dividers 44 defining a plurality of sub-compartments 46A to 46D, each sub-compartment configured to receive one of said structures.

When the insert 4 is arranged within the tank 2, one side 30 of the tank, adjacent the face 14 of the insert, comprises at least one inlet and at least one outlet. With reference to FIGS. 3A, 8 and 12, the tank according to a preferred embodiment of the present invention has two inlets and one outlet. The inlet communicates from an outside of the outer insulated tank 2 into the compartment 6 in use, and the outlet communicates from the compartment to an outside of the outer insulated tank in use (via drain pipe 40), such that in operation, the heat exchange fluid is introduced into the tank 2 (and thereby into the compartment 6) via said at least one inlet and removed from the compartment 6 and tank 2 via said at least one outlet.

The side wall 30 of the tank 2 is spaced from the face 14 of the insert 4, thus defining a void (not shown). The tank 2 is preferably constructed of steel to conform with ASTM A240.

In use, the tank 2 is filled with heat exchange fluid which does not freeze above −80° C. The heat exchange fluid is pumped into the tank 2 via the heat exchange fluid inlet of the tank 2 into the void at a pre-determined volumetric flow rate. Pressure is built up in the void as heat exchange fluid is forced through the restricted areas of the apertures 18, thus reducing the volumetric flow rate but increasing velocity of the fluid entering the compartment 6. The apertures 18 and baffle 20 provide improved distribution of cold fluid to all parts of the compartment 6 and minimise the occurrence of hot spots which would otherwise be likely to occur away from the inlet area. As the heat transfer fluid flows continuously through the tank 2 and compartment 6, heat is removed from the biological materials located within the compartment 6, and the heated heat exchange fluid leaving the compartment 6 and tank 2 will then be exchanged with a refrigeration system of the apparatus which continuously cools the heat exchange fluid. The heat exchange fluid itself exchanges heat with refrigerant in the refrigeration system. FIG. 32 is a piping and instrumentation diagram of a refrigeration system of the apparatus 10 according to one embodiment that continuously cools the heat exchange fluid. The refrigeration system includes a heat exchanger for exchanging heat between the heat transfer fluid and the refrigerant.

The apparatus 10 may further comprise a drier tank 50, specifically a blow down drier tank, configured to receive the one or more containers holding the biological material following freezing of the biological material in the immersion tank 2. The drier tank 50 is configured to dry any residual heat exchange fluid present on the container(s), to prevent contamination of the samples.

In preferred embodiments, the apparatus 10 inputs heat exchange fluid into both the immersion tank 2 and the drier tank 50. That is, heat exchange fluid may be selectively directed into the drier tank 50 to cool the drier tank. The apparatus 10 may comprise controls such as solenoid-controlled valves for selectively directing heat exchange fluid into one or both of the outer insulated tank 2 and the drier tank 50. For example, the apparatus may comprise three solenoid-controlled valves connected to the same source of heat exchange fluid in the apparatus. Two of the valves direct heat exchange fluid into the tank 2, and the third directs heat exchange fluid into the drier tank 50. The valves may be controlled depending on the flow required into each component, for example where a higher flow rate is required to be input into the immersion tank 2 (such as during a rapid cooling phase of the cooling method according to one embodiment that will be described in more detail below), the valves may be controlled to minimise or shut down flow into the drier tank 50 such that all fluid is directed into the tank 2. At other times, the fluid may be input into both the immersion tank 2 and the drier tank 50 such that the drier tank is maintained at approximately the same temperature as the immersion tank, ready for transfer of the biological material into the drier tank for drying and/or storage. Accordingly, in some embodiments, the drier tank 50 is configured to also be used as a storage vessel, for storing the containers of biological material. According to a preferred embodiment of the invention, the drier tank has a void or cavity in the wall arrangement defining the drier tank that is filled with the heat transfer fluid when the solenoid-controlled valves are open to cool the contents. The void or cavity in the wall arrangement may have a thickness or width of between about 1 mm and 5 mm, preferably about 2 mm.

### Two-Phase Cooling Preservation Method

The inventors have found that by increasing the rate of cooling at a specific stage of freezing, the biological product can be preserved with a reduced level of cryoprotectant, and in some cases, even without the use of cryoprotectant. Specifically, the present preservation method implements two-phase cooling, with slow cooling up to about the onset of liquid-solid phase transition, then rapid cooling from about the onset of liquid-solid phase transition. FIG. 30 is a generic freezing curve, illustrating how liquid-solid phase transition is accompanied by a rise in temperature from sub-zero temperatures following supercooling of the material. Nucleation begins at the onset of phase transition and continues into the solid freezing phase. The inventors have found that reducing the duration of nucleation to thereby reduce ice crystal formation in the sample produces a fast freezing effect similar to liquid nitrogen freezing but with reduced osmotic damage compared to conventional liquid nitrogen methods. Specifically, the present method involves increasing the cooling rate (ie initiating rapid freezing of the sample) from about the onset of liquid-solid phase transition to reduce the duration of nucleation of the biological material. In some cases, the reduction in freezing damage is so significant that no cryoprotectant is necessary. FIG. 3 illustrates a freeze curve of a sample of red blood cells in 0% cryoprotectant, frozen using the present two-phase cooling method. There is no rise in temperature during phase transition, due to rapid cooling being initiated at the onset thereof.

In one embodiment, a method of preserving a biological material comprises first determining the total surface area of an approximated geometry of the biological material, wherein the biological material and any packaging define a sample, estimating the thermal properties of the sample and performing computational fluid dynamics analysis on the sample via simulation of the sample being frozen within the apparatus 2 (more specifically, within the compartment 6) to investigate the influence of varying input parameters of the preservation system. Inputs/constraints of the simulation that may be investigated include the characteristics of the packaging and the characteristics of the racking systems utilised, an approximated geometry of the sample, thermal properties of the sample, the apparatus geometry, the predetermined arrangement of sample in the apparatus, a predetermined inlet temperature of heat exchange fluid, and a predetermined increase in temperature of the heat exchange fluid from inlet to outlet.

FIG. 4 illustrates example parameters for simulating freezing of an array of 13 cryovials arranged in compartment 6, each cryovial containing 0.5 ml blood. Each cryovial is modelled as being made of polypropylene and having a diameter of 6 mm, height of 27.5 mm, and wall thickness of 0.5 mm. The heat exchange fluid inflow is selected as 39 litres/minute. The compartment 6 is modelled as having a height of 35.5 mm. Movement of blood during freezing is ignored, i.e. the blood is assumed to be ‘solid’. The thermal properties of blood is based the assumption that it consists of 85% water and 15% protein. Thermal properties of biological material can be obtained through methods known to those skilled in the art, or looked up in thermal property tables known to those skilled in the art.

FIG. 5 illustrates example parameters for simulating freezing of an array of 13 cryovials arranged in compartment 6, each cryovial containing 2 ml blood. Each cryovial is modelled as being made of polypropylene and having a diameter of 13.5 mm, height of 48.8 mm, and wall thickness of 0.5 mm. The heat exchange fluid inflow is selected as 39 litres/minute. The compartment 6 is modelled as having a height of 57 mm.

The computational fluid dynamic analysis according to one embodiment involves dividing the biological material into geometrical increments (e.g. cylindrical shells for bottles or test tubes). For every one of these increments, a conservation of energy equation is solved, i.e. for a given time-step, a certain amount of energy is removed from a shell, resulting in a decrease in temperature of that shell. The amount of energy removed is a function of the temperatures of the adjacent shells, as well as the resistance to heat flow between the shells. This involves taking into account thermal properties of the biological material as a function of temperature.

Analysis is performed assuming that the sample may be treated as a solid mass having a starting temperature of 2° C., and having thermal properties which can be identified, estimated or calculated using methods that will be known to the person skilled in the art.

On the basis of the total surface area of the product, load volume of the product in the tank, a pre-selected inlet temperature of heat exchange fluid, a pre-selected acceptable outlet temperature of heat exchange fluid (e.g. 3° C. greater than the inlet temperature), the thermal properties of the product (including cryoprotectant) and packaging and pre-selected velocity of fluid through the tank, etc, the rate of temperature reduction of product can be simulated as detailed above.

FIG. 6 illustrates a plan view of heat exchange fluid flow through the compartment midplane through the cryovials, obtained from fluid dynamics analysis of the model of FIG. 5. The modelling shows a uniform heat removal rate with respect to the cryovials in the compartment. FIGS. 7A and 7B illustrate the heat exchange fluid flow from front and rear perspective views of the tank respectively.

The temperature-time plots in FIGS. 8 and 9 correspond to the analysis on the central 0.5 ml cryovial of the model of FIG. 4, frozen to about −80° C. within about 65 seconds and to about −51° C. within about 80 seconds respectively. From these two figures, according to preferred embodiments of the invention, the cryovials frozen to about −51° C. achieves better preservation results compared to cryovials frozen to about −80° C. The graph plots the temperature at various shells through the cryovials, from the outside (“PG Temperature 2.99 mm PPoutside”) to the core (“PG Temperature 0 mm”). FIG. 10 is a temperature-time plot of the central cryovial, frozen at the same rate as the simulation of FIG. 8, but with the baffle 20 removed from the insert 4, illustrating the effectiveness of the baffle at improving circulation of heat transfer fluid through the compartment 6.

The temperature-time plots in FIGS. 11 and 12 correspond to the analysis on the central 2 ml cryovial of the model of FIG. 5, frozen to about −80° C. within about 185 seconds and to about −51° C. within about 220 seconds respectively.

FIG. 13A illustrate example parameters for simulating freezing of a blood bag suspended within compartment 6. The dimensions of the bag are 14.5 cm wide, 7.6 cm high and 4 mm thick, and the bag contains 10 to 30 ml of blood. The wall of the bag is modelled as being made of ethylene vinyl acetate, with a thickness of 0.13 mm. The heat exchange fluid inflow is selected as about 39 litres/minute, and in a direction substantially perpendicular to the narrow side face of the bag. The compartment 6 is modelled as having a height of 80 mm. FIG. 13B illustrates a model having similar parameters as the model of FIG. 13A, but with the heat transfer fluid flowing into the compartment in a direction substantially perpendicular to the wider front face of the bag.

FIG. 14 is a temperature-time plot of the blood bag of the model of FIG. 13A, frozen to about −80° C. within about 180 seconds. FIG. 15 is a temperature-time plot of the blood bag of the model of FIG. 13B, frozen to about −80° C. within about 270 seconds. FIG. 16 is a temperature-time plot of the blood bag of the model of FIG. 13A, frozen to about −51° C. within about 180 seconds.

The onset of liquid-solid phase transition for the sample is approximated. In one embodiment, the onset of liquid-solid phase transition is approximated from the cooling curve obtained from one or more test results of samples of the material undergoing freezing at a consistent cooling rate. Onset of liquid-solid phase transition may additionally or alternatively be determined/confirmed from the cooling curve of the sample obtained via the computational fluid dynamics analysis described above.

For a predetermined slow cooling rate, the average temperature reduction rate of the core of the sample at a predetermined sample surface temperature up to about the onset of phase transition is determined (from the computational fluid dynamics model). The heat exchange fluid flow rate into immersion tank 2 required to achieve the slow cooling rate may then be determined.

The heat exchange fluid flow rate required for achieving a predetermined rapid cooling rate is similarly determined via analysis of the average temperature reduction rate of the core of the sample at a predetermined sample surface temperature from about the onset of phase transition.

Once the analysis is complete, the sample may then be cooled in the compartment 6 of the apparatus as described above, first at the slow cooling rate up to about the onset of phase transition, then at the rapid cooling rate from about the onset of phase transition. The sample is cooled at at least about 100° C. per minute until a predetermined end temperature is achieved.

To achieve the required heat exchange fluid flow rate for rapid cooling, the pump duty of the pump of the apparatus 10 which inputs the heat exchange fluid into the tank 2 is increased. Additionally or alternatively, where the pump supplies tank 2 as well as drier tank 50 using selectively-controllable valves as described above, the supply to the drier tank 50 may be temporarily suspended to increase flow into the immersion tank 2.

It is envisaged that in some embodiments, the method described above may be used to effectively preserve biological material without the use of any cryoprotectant.

Table 1 includes test results on red blood cells in 0% cryoprotectant, obtained using the method described above. A recovery rate of approximately 98% was achieved. Specific parameters of the test method are as follows: The slow cooling rate was between 5 and 10° C., achieved with a heat exchange fluid flow rate of 5 litres/minute. The rapid cooling rate was above 200° C., achieved with a heat exchange fluid flow rate of 50 litres/minute. Table 2 sets out the cooling rate over time. Onset of liquid-solid phase transition was determined at −0.5° C. The samples were frozen to −51° C., and the total duration of the processing was 3 minutes on average. The vials in which the samples are contained are made from polypropylene and are 2 ml self-standing vials. Vials made from other thermoplastic material, other plastic material, or other material may also be used with embodiments of the present invention. Prior to cell counting, the samples were thawed using the thawing method described below, using thawing medium at 37.5° C. for 55 seconds.

TABLE 1
Red blood cells in 0%, 4% and 8% cryoprotectant

| | | Cell count immediately post freeze | | | Overall Result | | |
|---|---|---|---|---|---|---|---|
| | | 0% | 4% | 10% | 0% | 4% | 10% |
| Replicate | | DMSO | DMSO | DMSO | DMSO | DMSO | DMSO |
| | Phase 1 | | | | | | |
| 1 | Sceptre cell count-1 | | | 2.11E+05 | | | 51.09% |
| 2 | Sceptre cell count-2 | | | 4.87E+05 | | | 117.92% |
| 3 | Sceptre cell count-3 | | | 4.24E+05 | | | 102.66% |
| 4 | Sceptre cell count-4 | | | 4.38E+05 | | | 106.05% |
| 5 | Sceptre cell count-5 | | | 4.07E+05 | | | 98.55% |
| 6 | Sceptre cell count-6 | | | 4.00E+05 | | | 96.85% |
| 7 | Sceptre cell count-7 | | | 4.67E+05 | | | 113.08% |
| 8 | Sceptre cell count-8 | | | 4.35E+05 | | | 105.33% |
| | RBC unfrozen blood | | | 4.13E+05 | | | |
| | count | | | | | | |
| | RBC count - Adjusted | | | 4.13E+09 | | | |
| | Mean | | | 4.09E+05 | | | |
| | Mean Adjusted | | | 4.09E+09 | | | |
| | % of original | | | 98.90% | | | |
| | Phase 2 | | | | | | |
| 9 | Sceptre cell count-1 | 4.67E+05 | 4.56E+05 | | 98.36% | 96.00% | |
| 10 | Sceptre cell count-2 | 4.18E+05 | 4.39E+05 | | 88.06% | 92.51% | |
| 11 | Sceptre cell count-3 | 4.78E+05 | 4.40E+05 | | 100.63% | 92.65% | |
| 12 | Sceptre cell count-4 | 5.03E+05 | 4.88E+05 | | 105.79% | 102.80% | |
| 13 | Sceptre cell count-5 | 4.50E+05 | 4.54E+05 | | 94.80% | 95.56% | |
| 14 | Sceptre cell count-6 | 4.10E+05 | 5.11E+05 | | 86.27% | 107.49% | |
| 15 | Sceptre cell count-7 | 5.43E+05 | 4.73E+05 | | 114.34% | 99.62% | |
| 16 | Sceptre cell count-8 | 4.65E+05 | 5.02E+05 | | 97.79% | 105.66% | |
| 17 | Sceptre cell count-9 | 4.49E+05 | 4.16E+05 | | 94.59% | 87.64% | |
| 18 | Sceptre cell count-10 | 5.04E+05 | 4.74E+05 | | 106.02% | 99.85% | |
| 19 | Sceptre cell count-11 | | 4.85E+05 | | | 102.08% | |
| | RBC unfrozen blood | 4.75E+05 | 4.75E+05 | | | | |
| | count | | | | | | |
| | RBC count - Adjusted | 4.75E+09 | 4.75E+09 | | | | |
| | Mean | 4.69E+05 | 4.67E+05 | | | | |
| | Mean Adjusted | 4.69E+09 | 4.67E+09 | | | | |
| | % of original | 98.60% | 98.30% | | | | |
| | Phase 3 | | | | | | |
| 20 | Sceptre cell count-1 | 4.31E+05 | 4.58E+05 | | 93.59% | 99.11% | |
| 21 | Sceptre cell count-2 | 4.49E+05 | 4.90E+05 | | 97.70% | 106.02% | |
| 22 | Sceptre cell count-3 | 4.57E+05 | 4.43E+05 | | 99.37% | 95.82% | |
| 23 | Sceptre cell count-3 | 4.60E+05 | 4.52E+05 | | 99.96% | 97.90% | |
| 24 | Sceptre cell count-4 | 4.66E+05 | 4.90E+05 | | 101.33% | 105.97% | |
| 25 | Sceptre cell count-5 | 4.28E+05 | 4.74E+05 | | 93.09% | 102.60% | |
| 26 | Sceptre cell count-6 | 4.51E+05 | 4.06E+05 | | 98.04% | 87.97% | |
| 27 | Sceptre cell count-7 | 4.30E+05 | 4.74E+05 | | 93.50% | 102.60% | |
| 28 | Sceptre cell count-8 | 4.55E+05 | 4.65E+05 | | 98.93% | 100.56% | |
| 29 | Sceptre cell count-9 | 4.59E+05 | 4.18E+05 | | 99.72% | 90.52% | |
| | RBC unfrozen blood | 4.60E+05 | 4.62E+05 | | | | |
| | count | | | | | | |
| | RBC count - Adjusted | 4.60E+09 | 4.62E+09 | | | | |
| | Mean | 4.49E+05 | 4.57E+05 | | | | |
| | Mean Adjusted | 4.49E+09 | 4.57E+09 | | | | |
| | % of original | 97.60% | 98.90% | | | | |
| | Phase 4 | | | | | | |
| 30 | Sceptre cell count-1 | 4.56E+05 | | 5.47E+05 | 97.44% | | 109.98% |
| 31 | Sceptre cell count-2 | 4.25E+05 | | 5.47E+05 | 90.81% | | 109.96% |
| 32 | Sceptre cell count-3 | 4.78E+05 | | 5.93E+05 | 102.16% | | 119.34% |
| 33 | Sceptre cell count-4 | 4.07E+05 | | 5.32E+05 | 87.05% | | 107.06% |
| 34 | Sceptre cell count-5 | 4.14E+05 | | 4.68E+05 | 88.48% | | 94.25% |
| 35 | Sceptre cell count-6 | 4.86E+05 | | 5.50E+05 | 103.82% | | 110.70% |
| 36 | Sceptre cell count-7 | 5.63E+05 | | 4.91E+05 | 120.24% | | 98.85% |
| 37 | Sceptre cell count-8 | 4.47E+05 | | 5.16E+05 | 95.60% | | 103.86% |
| 38 | Sceptre cell count-9 | 4.47E+05 | | | 95.51% | | |
| | RBC unfrozen blood | 4.68E+05 | | 4.97E+05 | | | |
| | count | | | | | | |
| | RBC count - Adjusted | 4.68E+09 | | 4.97E+09 | | | |
| | Mean | 4.58E+05 | | 5.31E+05 | | | |
| | Mean Adjusted | 4.58E+09 | | 5.31E+09 | | | |
| | % of original | 98.00% | | 106.70% | | | |
| | Phase 5 | | | | | | |
| 39 | Sceptre cell count-1 | 4.39E+05 | | 4.94E+05 | 101.20% | | 113.82% |
| 40 | Sceptre cell count-2 | 4.26E+05 | | 5.00E+05 | 98.02% | | 115.28% |
| 41 | Sceptre cell count-3 | 4.50E+05 | | 4.50E+05 | 103.57% | | 103.64% |
| 42 | Sceptre cell count-4 | 4.39E+05 | | 4.82E+05 | 101.04% | | 111.01% |
| 43 | Sceptre cell count-5 | 4.44E+05 | | 4.82E+05 | 102.33% | | 111.08% |
| 44 | Sceptre cell count-6 | 4.10E+05 | | 5.03E+05 | 94.31% | | 115.99% |
| 45 | Sceptre cell count-7 | 4.40E+05 | | 4.17E+05 | 101.43% | | 95.99% |
| 46 | Sceptre cell count-8 | 4.17E+05 | | 4.94E+05 | 95.95% | | 113.89% |
| 47 | Sceptre cell count-9 | 4.34E+05 | | 4.34E+05 | 99.91% | | 100.02% |
| 48 | Sceptre cell count-10 | | | 4.38E+05 | | | 100.90% |
| 49 | Sceptre cell count-11 | | | 4.52E+05 | | | 104.17% |
| 50 | Sceptre cell count-12 | | | 4.65E+05 | | | 107.05% |
| 51 | Sceptre cell count-13 | | | 5.02E+05 | | | 115.60% |
| 52 | Sceptre cell count-14 | | | 4.97E+05 | | | 114.52% |
| 53 | Sceptre cell count-15 | | | 4.42E+05 | | | 101.89% |
| 54 | Sceptre cell count-16 | | | 4.49E+05 | | | 103.36% |
| 55 | Sceptre cell count-17 | | | 4.03E+05 | | | 92.95% |
| 56 | Sceptre cell count-18 | | | 4.44E+05 | | | 102.26% |
| | RBC unfrozen blood | 4.34E+05 | | 4.34E+05 | | | |
| | count | | | | | | |
| | RBC count - Adjusted | 4.34E+09 | | 4.34E+09 | | | |
| | Mean | 4.33E+05 | | 4.64E+05 | | | |
| | Mean Adjusted | 4.33E+09 | | 4.64E+09 | | | |
| | % of original | 99.70% | | 106.80% | | | |
| | Phase 6 | | | | | | |
| 57 | Sceptre cell count-1 | | 4.15E+05 | 4.24E+05 | | 98.41% | 99.27% |
| 58 | Sceptre cell count-2 | | 4.37E+05 | 4.39E+05 | | 103.58% | 102.90% |
| 59 | Sceptre cell count-3 | | 4.27E+05 | 4.62E+05 | | 101.11% | 108.15% |
| 60 | Sceptre cell count-4 | | 4.37E+05 | 4.20E+05 | | 103.60% | 98.36% |
| 61 | Sceptre cell count-5 | | 4.77E+05 | 4.33E+05 | | 112.99% | 101.48% |
| 62 | Sceptre cell count-6 | | 4.28E+05 | 4.39E+05 | | 101.40% | 102.72% |
| 63 | Sceptre cell count-7 | | 4.37E+05 | 4.54E+05 | | 103.60% | 106.30% |
| 64 | Sceptre cell count-8 | | 4.27E+05 | 5.49E+05 | | 101.23% | 128.48% |
| 65 | Sceptre cell count-9 | | 4.20E+05 | 4.55E+05 | | 99.53% | 106.49% |
| 66 | Sceptre cell count-10 | | 4.71E+05 | 5.11E+05 | | 111.54% | 119.77% |
| 67 | Sceptre cell count-11 | | | 4.29E+05 | | | 100.37% |
| 68 | Sceptre cell count-12 | | | 4.60E+05 | | | 107.63% |
| 69 | Sceptre cell count-13 | | | 4.08E+05 | | | 95.60% |
| 70 | Sceptre cell count-14 | | | 4.15E+05 | | | 97.19% |
| | RBC unfrozen blood | | 4.22E+05 | 4.27E+05 | | | |
| | count | | | | | | |
| | RBC count - Adjusted | | 4.22E+09 | 4.27E+09 | | | |
| | Mean | | 4.38E+05 | 4.50E+05 | Mean average | | |
| | Mean Adjusted | | 4.38E+09 | 4.50E+09 | 0% | 4% | 10% |
| | | | | | DMSO | DMSO | DMSO |
| | % of original | | 103.50% | 105.20% | 101.10% | 103.60% | 105.08% |

TABLE 2
Two-stage cooling rates - 0.5 ml cryovials

| | | | Temperature |
|---|---|---|---|
| Time (seconds) | Temperature | Speed (° C./min) | reduction (° C.) |
| 0-4 | +1-+0.34 | 9.9 | 0.66 |
| 5-8 | +0.34-−0.32 | 9.9 | 0.66 |
| 9-12 | −0.32-−0.98 | 9.9 | 0.66 |
| 13-16 | −0.98-−1.64 | 9.9 | 0.66 |
| 17-20 | −1.64-−36 | 515.4 | 34.36 |
| 21-24 | −36-−45 | 135 | 9 |
| 25-28 | −45-−49 | 60 | 4 |

### Method of Determining Amount of Cryoprotectant Required for Preservation Process

In some cases, cryoprotectant may be required to minimise cell damage during the preservation process. Accordingly, in another aspect, there is provided a method of determining the amount of cryoprotectant to be added to a biological material prior to preservation. The method comprises first determining the total surface area of an approximated geometry of the biological material, including an initial amount of cryoprotectant, to be preserved, wherein the biological material, cryoprotectant and any packaging define a sample, estimating thermal the properties of the sample and performing computational fluid dynamics analysis on the sample within the apparatus 2 (more specifically, within the compartment 6) to investigate the influence of varying input parameters of the preservation system. Inputs/constraints of the simulation that may be investigated include include the characteristics of the packaging and the characteristics of the racking systems utilised, an approximated geometry of the sample, thermal properties of the sample, the apparatus geometry, the predetermined arrangement of sample in the apparatus, a predetermined inlet temperature of heat exchange fluid, and a predetermined increase in temperature of the heat exchange fluid from inlet to outlet.

The onset of liquid-solid phase transition for the sample is approximated. In one embodiment, the onset of liquid-solid phase transition is approximated from the cooling curve obtained from one or more test results of samples of the material undergoing freezing at a consistent cooling rate. Onset of liquid-solid phase transition may additionally or alternatively be determined/confirmed from the cooling curve of the sample obtained via the computational fluid dynamics analysis described above.

For a predetermined slow cooling rate, the average temperature reduction rate of the core of the sample at a predetermined sample surface temperature up to about the onset of phase transition is determined (from the computational fluid dynamics model described above). The heat exchange fluid flow rate into immersion tank 2 required to achieve the slow cooling rate may then be determined.

The heat exchange fluid flow rate required for achieving a predetermined rapid cooling rate is similarly determined via analysis of the average temperature reduction rate of the core of the sample at a predetermined sample surface temperature from about the onset of phase transition. If the heat exchange fluid flow rate calculated at this step corresponds to a pump duty or an evaporator duty of the apparatus that is above a predetermined pump duty or predetermined evaporator duty respectively, an amount of cryoprotectant that is a predetermined amount more than the initial amount is selected to define a new initial amount. If, on the other hand, the heat exchange fluid flow rate calculated at this step corresponds to a pump duty or an evaporator duty that is equal to or less than the predetermined pump duty or predetermined evaporator duty respectively (ie the heat exchange fluid flow rate is acceptable from a practical standpoint, e.g. if the pump duty is acceptable based on the viscosity of heat exchange fluid at the selected temperature or if the evaporator duty is acceptable based on the required heat removal), that initial amount of cryoprotectant is selected as the amount of cryoprotectant to be added to the biological material prior to preservation.

If the heat exchange fluid flow rate calculated corresponds to a pump duty or an evaporator duty that is above the predetermined pump duty or predetermined evaporator duty respectively, the method steps are repeated until the heat exchange fluid flow rate calculated corresponds to a pump duty or an evaporator duty that is equal to or less than the predetermined pump duty or predetermined evaporator duty respectively.

In one embodiment, the initial amount of cryoprotectant is zero. If the calculation steps are to be repeated, the predetermined amount of cryoprotectant more than the initial amount may be increased in regular increments, such as 1% more in each repetition.

Once the appropriate amount of cryoprotectant is determined using the method above, samples of the biological material may then be prepared with the calculated amount of cryoprotectant for preserving using the apparatus 10 as described above.

The predetermined slow and/or rapid cooling rates may be identified based on conventional protocols or based on trials or analyses conducted on specific samples of biological materials. In one embodiment, the slow cooling rate is up to about 10° C. per minute. The slow cooling rate may be between about 0.1° C. and about 10° C. per minute.

In one embodiment, the rapid cooling rate is greater than about 100° C. per minute. The rapid cooling rate may be greater than about 200° C. per minute.

### Thawing Apparatus and Methods

With reference to FIG. 17, there is also provided a thawing apparatus 100 for thawing frozen preserved biological material comprising a thawing tank 102 for receiving biological material. The biological material may be held within the tank in a structure comprising one or more of a tray, a rack and a basket. The structure may be identical to the structure used to hold the biological material in the immersion tank 2, so that the biological material may be conveniently transferred from the freezing apparatus to the thawing apparatus. The thawing apparatus 100 comprises a tank inlet via which thawing fluid is introduced into the tank 102, and a tank outlet via which thawing fluid is removed from the tank, and the tank is configured to accommodate a continuous thawing fluid flow through the apparatus such that, in operation, biological material in the tank is immersed in the thawing fluid to exchange heat with the thawing fluid for thawing of the biological material. The thawing tank may comprises a baffle (not shown) configured to direct flow of the thawing fluid through the tank along one or more specific pathways.

In one embodiment, a method of thawing a frozen preserved biological material, comprises first determining the total surface area of an approximated geometry of the biological material, wherein the biological material and any packaging define a sample, estimating thermal properties of the sample and performing computational fluid dynamics analysis on the sample via simulation of the sample being thawed within the thawing tank 102 to investigate the influence of varying input parameters of the thawing system. Inputs/constraints of the simulation that may be investigated include the characteristics of the packaging and the characteristics of the racking systems utilised, an approximated geometry of the sample; thermal properties of the sample; the apparatus geometry; predetermined arrangement of sample in the apparatus; a predetermined inlet temperature of thawing fluid; and a predetermined decrease in temperature of the thawing fluid from inlet to outlet.

FIG. 18 illustrates example parameters for simulating thawing of an array of 13 cryovials arranged in the thawing tank, each cryovial containing 0.5 ml blood. Each cryovial is modelled as being made of polypropylene and having a diameter of 6 mm, height of 27.5 mm, and wall thickness of 0.5 mm. The thawing fluid inflow is selected as 39 litres/minute. The enclosure of the thawing tank is modelled as having a height of 35.5 mm.

FIG. 19 illustrates example parameters for simulating thawing of an array of 13 cryovials arranged in compartment 6, each cryovial containing 2 ml blood. Each cryovial is modelled as being made of polypropylene and having a diameter of 13.5 mm, height of 48.8 mm, and wall thickness of 0.5 mm. The thawing fluid inflow is selected as 39 litres/minute. The enclosure of the thawing tank is modelled as having a height of 57 mm.

The temperature-time plots in FIGS. 20 and 21 correspond to the analysis on the central 0.5 ml and 2 ml cryovials respectively of the models of FIGS. 19 and 20, thawed from about −80° C.

The temperature-time plots in FIGS. 22, 23 and 24 correspond to the analysis on the central 0.5 ml of the model of FIG. 19 thawed from about −51° C., with the cryovials containing red blood cells without cryoprotectant, red blood cells with 4% dimethyl sulfoxide (DMSO) as cryoprotectant and red blood cells with 10% dimethyl sulfoxide (DMSO) as cryoprotectant respectively. FIGS. 27 and 28 are reference plots of apparent specific heat and thermal conductivity respectively for blood mixtures with varying DMSO concentrations. The reference plots may be used to inform input parameters for investigation of the effect of cryoprotectant concentration.

FIG. 25 illustrates example parameters for simulating freezing of a blood bag suspended within an enclosure of the thawing tank 102. The dimensions of the bag are 14.5 cm wide, 7.6 cm high and 4 mm thick, and the bag contains 10 to 30 ml of blood. The wall of the bag is modelled as being made of ethylene vinyl acetate, with a thickness of 0.13 mm. The thawing fluid inflow is selected as about 39 litres/minute, and in a direction substantially perpendicular to the narrow side face of the bag. The enclosure of the thawing tank is modelled as having a height of about 320 mm.

The onset of solid-liquid phase transition for the sample is approximated. In one embodiment, the onset of solid-liquid phase transition is approximated from the cooling curve obtained from one or more test results of samples of the material undergoing freezing at a consistent cooling rate. Onset of solid-liquid phase transition may additionally or alternatively be determined/confirmed from the thawing curve of the sample obtained via the computational fluid dynamics analysis described above.

The sample is then thawed for a duration up to the onset of solid-liquid transition. It has been found that thawing frozen samples up to the onset of transition increases cell viability. After thawing, the sample is maintained at a temperature of about 2° C.

In some embodiments, the thawing fluid is water input at a temperature of 37° C.

While various embodiments of the present invention have been described above, it should be understood that they have been presented by way of example only, and not by way of limitation. It will be apparent to a person skilled in the relevant art that various changes in form and detail can be made therein without departing from the spirit and scope of the invention. Thus, the present invention should not be limited by any of the above described exemplary embodiments.

The reference in this specification to any prior publication (or information derived from it), or to any matter which is known, is not, and should not be taken as an acknowledgment or admission or any form of suggestion that that prior publication (or information derived from it) or known matter forms part of the common general knowledge in the field of endeavor to which this specification relates.

Throughout this specification and the claims which follow, unless the context requires otherwise, the word “comprise”, and variations such as “comprises” and “comprising”, will be understood to imply the inclusion of a stated integer or step or group of integers or steps but not the exclusion of any other integer or step or group of integers or steps.

1. An apparatus for preserving biological material, comprising an insert configured to be arranged within an outer insulated tank, the insert defining a compartment for receiving biological material, wherein inflow of a heat exchange fluid into the compartment from the outer insulated tank is at or adjacent one face of the insert, and outflow of the heat exchange fluid out of the compartment to the outer insulated tank is at or adjacent said face of the insert, the compartment comprising a wall having a series of apertures to accommodate a continuous heat exchange fluid flow through the apparatus such that, in operation, biological material in the compartment is immersed in the heat exchange fluid to exchange heat with the heat exchange fluid for freezing of said biological material.

2. The apparatus of claim 1, wherein the insert comprises a baffle configured to direct flow of the heat exchange fluid through the compartment along one or more specific pathways.

3. The apparatus of claim 1, including a structure receivable in the compartment for holding the biological material, wherein the structure is one or more of a tray, a rack and a basket.

4. The apparatus of claim 3, wherein the compartment comprises a plurality of internal dividers defining a plurality of sub-compartments, each sub-compartment configured to receive one of said structures.

5. The apparatus of claim 1, wherein the outer insulated tank comprises:
one side adjacent said face of the insert when the insert is arranged within the outer insulated tank, said side comprising at least one inlet and at least one outlet, the inlet communicating from an outside of the outer insulated tank into the compartment in use, and the outlet communicating from the compartment to an outside of the outer insulated tank in use, wherein, in operation, said heat exchange fluid is introduced into the tank via said at least one inlet and removed from the tank via said at least one outlet.

6. The apparatus of claim 1, further comprising a drier tank configured to receive one or more containers holding said biological material following freezing of said biological material in said compartment, the drier tank being configured to dry residual fluid present on said container(s).

7. The apparatus of claim 6, wherein at least one of:
a. heat exchange fluid is directed into the drier tank to cool said drier tank;
b. apparatus comprises solenoid-controlled valves for selectively directing heat exchange fluid into one or both of the outer insulated tank and the drier tank; and
c. the drier tank is configured to store said one or more containers holding said biological material at a predetermined temperature.

8-9. (canceled)

10. A method of preserving biological material, comprising:
a. determining the total surface area of an approximated geometry of a sample of the biological material, wherein the biological material and any packaging define a sample;
b. estimating thermal properties of the sample;
c. performing computational fluid dynamics analysis on the sample within said compartment of the apparatus of claim 1 based on flow constraints including any one or more of: an approximated geometry of the sample; thermal properties of the sample; the apparatus geometry; predetermined arrangement of sample in the apparatus; a predetermined inlet temperature of heat exchange fluid; and a predetermined increase in temperature of the heat exchange fluid from inlet to outlet;
d. approximating the onset of liquid-solid phase transition for the sample;
e. determining an average temperature reduction rate of the core of the sample at a predetermined sample surface temperature up to about the onset of phase transition and corresponding heat exchange fluid flow rate required to obtain a predetermined slow cooling rate;
f. determining an average temperature reduction rate of the core of the sample at a predetermined sample surface temperature from about the onset of phase transition and corresponding heat exchange fluid flow rate required to obtain a predetermined rapid cooling rate;
g. cooling the sample in said compartment of the apparatus of claim 1 at said slow cooling rate up to about the onset of phase transition;
h. cooling the sample in said compartment at the rapid cooling rate from about the onset of phase transition.

11. The method of claim 10, wherein the sample does not contain cryoprotectant.

12. A method of preserving a biological material within an apparatus having a compartment in which the biological material is stored, and a pump arrangement for pumping a heat exchange fluid into and/or from the compartment, the method comprising:
adjusting an inflow of heat exchange fluid into the compartment and/or an outflow of heat exchange fluid from the compartment based on thermal properties of the biological material and at least one of a pumping capability of the pumping arrangement, the heat exchange fluid, and a temperature of the biological material.

13. A method of determining an amount of cryoprotectant to be added to a biological material prior to preservation, comprising:
a. determining the total surface area of an approximated geometry of the biological material, including an initial amount of cryoprotectant, to be preserved, wherein the biological product, cryoprotectant and any packaging define a sample;
b. estimating thermal properties of the sample;
c. performing computational fluid dynamics analysis on the sample within said compartment of the apparatus of claim 1 based on flow constraints including any one or more of: an approximated geometry of the sample; thermal properties of the sample; the apparatus geometry; predetermined arrangement of sample in the apparatus; a predetermined inlet temperature of heat exchange fluid; and a predetermined increase in temperature of the heat exchange fluid from inlet to outlet;
d. approximating the onset of liquid-solid phase transition for the sample;
e. determining an average temperature reduction rate of the core of the sample at a predetermined sample surface temperature up to about the onset of phase transition and corresponding heat exchange fluid flow rate required to obtain a predetermined slow cooling rate;
f. determining an average temperature reduction rate of the core of the sample at a predetermined sample surface temperature from about the onset of phase transition and corresponding heat exchange fluid flow rate required to obtain a predetermined rapid cooling rate;
g. if the heat exchange fluid flow rate calculated at step (f) corresponds to a pump duty or an evaporator duty of the apparatus that is above a predetermined pump duty or predetermined evaporator duty respectively, selecting an amount of cryoprotectant that is a predetermined amount more than the initial amount to define a new initial amount or, if the heat exchange fluid flow rate calculated at step (f) corresponds to a pump duty or an evaporator duty that is equal to or less than the predetermined pump duty or predetermined evaporator duty respectively, selecting the initial amount of cryoprotectant as said amount of cryoprotectant to be added to a biological material prior to preservation; and
h. if the heat exchange fluid flow rate calculated at step (f) corresponds to a pump duty or an evaporator duty that is above the predetermined pump duty or predetermined evaporator duty respectively, repeating steps (a) to (g) until the heat exchange fluid flow rate calculated at step (f) corresponds to a pump duty or an evaporator duty that is equal to or less than the predetermined pump duty or predetermined evaporator duty respectively.

14. The method of claim 13, wherein the initial amount of cryoprotectant prior to any repetition of steps (a) to (g) is zero.

15. The method of claim 10, wherein the slow cooling rate is one of:
a. up to about 10° C. per minute; or
b. between about 0.1° C. and about 10° C. per minute.

16. (canceled)

17. The method of claim 10, wherein the rapid cooling rate is one of:
a. greater than about 100° C. per minute; or
b. greater than about 200° C. per minute.

18. (canceled)

19. The method of claim 10, wherein at least one of:
a. the onset of liquid-solid phase transition is approximated from a cooling curve of the sample undergoing freezing at a consistent cooling rate; or
b. the cooling curve of the sample undergoing freezing is obtained from said computational fluid dynamics analysis on the sample.

20. (canceled)

21. An apparatus for thawing frozen preserved biological material comprising a thawing tank for receiving biological material, said biological material being held within the tank in a structure comprising one or more of a tray, a rack and a basket, a tank inlet via which thawing fluid is introduced into the tank, and a tank outlet via which thawing fluid is removed from the tank, wherein the tank is configured to accommodate a continuous thawing fluid flow through the apparatus such that, in operation, biological material in the tank is immersed in the thawing fluid to exchange heat with the thawing fluid for thawing of said biological material.

22. The apparatus of claim 21, wherein at least one of:
a. a rate at which the thawing fluid is introduced in the tank via the tank inlet is controllable to control a rate at which the biological material is heated so as to prevent from damaging the biological material; or
b. the tank comprises a baffle configured to direct flow of the thawing fluid through the tank along one or more specific pathways.

23. (canceled)

24. A method of thawing a frozen preserved biological material, comprising:
a. determining the total surface area of an approximated geometry of the biological material, wherein the biological material and any packaging define a sample;
b. estimating thermal properties of the sample;
c. performing computational fluid dynamics analysis on the sample within said tank of a thawing apparatus according to claim 19 based on flow constraints including any one or more of: an approximated geometry of the sample; thermal properties of the sample; the apparatus geometry;
predetermined arrangement of sample in the apparatus; a predetermined inlet temperature of thawing fluid; and a predetermined decrease in temperature of the thawing fluid from inlet to outlet;
d. approximating the onset of solid-liquid phase transition for the sample; and
e. thawing the frozen preserved biological product for a duration up to the onset of solid-liquid transition determined at step (d).

25. The method of claim 24, wherein the inlet temperature of the thawing fluid is about 37° C.

26. The method of claim 24, wherein at least one of:
a. the onset of solid-liquid phase transition is approximated from a cooling curve of the sample undergoing freezing at a consistent cooling rate; and
b. the thawing curve of the sample undergoing freezing is obtained from said computational fluid dynamics analysis on the sample.

27. (canceled)
